(19) United States
(12) Patent Application Publication
(10) Pub. No.: US 2025/0306133 A1
(43) Pub. Date: Oct. 2, 2025

(54) HALL SENSOR WITH MAGNETIC CONCENTRATORS

(71) Applicant: TEXAS INSTRUMENTS INCORPORATED, DALLAS, TX (US)

(72) Inventors: Anindya PODDAR, SUNNYVALE, CA (US); Yi YAN, SAN JOSE, CA (US); Dok Won LEE, MOUNTAIN VIEW, CA (US)

(21) Appl. No.: 18/620,073

(22) Filed: Mar. 28, 2024

(51) Int. Cl. G01R 33/00; G01R 33/07

(52) U.S. Cl. CPC G01R 33/0011; G01R 33/0047; G01R 33/0052; G01R 33/07

(57) ABSTRACT

In an example, a Hall sensor can include an IC die formed on a lead frame that is configured to conduct a current, the IC die being configured to sense a magnetic field resulting from the current. The Hall sensor can include at least one magnetic permeability material film formed on the IC die. The Hall sensor can include at least one permalloy material layer formed on the respective at least one magnetic permeability material film, the at least one magnetic permeability material film and the at least one permalloy material layer combining to provide a magnetic concentrator providing concentration of the magnetic field.

### TECHNICAL FIELD

The present application relates to a Hall sensor and more particularly to magnetic concentrators as implemented in electronic component packages.

### BACKGROUND

Hall sensors are utilized in many modern electronic systems to sense the presence and in some cases the strength of a magnetic field. Hall sensors can be used as a basis for current measurement, such as in motor systems, energy distribution systems, appliances, power delivery, and the like. Magnetic field sensing is also often applied for position or proximity sensing, such as industrial, safety and other mechanical applications. The Hall Effect occurs when a magnetic field is oriented perpendicular to an electric current. Typical Hall sensors usually include a strip or plate of an electrically conductive material with an electric current flowing through the plate. When the plate is positioned in a magnetic field such that a component of the field is perpendicular to the plate, a Hall voltage is generated within the plate in a direction that is perpendicular to both the direction of the magnetic field and the direction of the current flow.

### SUMMARY

The present disclosure relates to systems and methods of manufacture for a Hall sensor having layered magnetic concentrators.

In an example, a Hall sensor can include an IC die formed on a lead frame that is configured to conduct a current, the IC die being configured to sense a magnetic field resulting from the current. The Hall sensor can include at least one magnetic permeability material film formed on the IC die. The Hall sensor can include at least one permalloy material layer formed on the respective at least one magnetic permeability material film, the at least one magnetic permeability material film and the at least one permalloy material layer combining to provide a magnetic concentrator providing concentration of the magnetic field.

In yet another example, a method of manufacturing a Hall sensor can include forming an IC die on a lead frame that is configured to conduct current, the IC die being configured to sense a magnetic field resulting from the current. The method of manufacturing a Hall sensor can include forming at least one magnetic permeability material film formed on the IC die. The method of manufacturing a Hall sensor can include forming at least one permalloy material layer formed on the respective at least one magnetic material film, the at least one magnetic permeability material film and the at least one permalloy material layer combining to provide a magnetic concentrator providing concentration of the magnetic field.

In an example, a Hall sensor system can include a lead frame configured to conduct a current. The Hall sensor system can include an integrated circuit (IC) die formed on the lead frame, the IC die being configured to sense a magnetic field resulting from the current. The Hall sensor system can include at least one magnetic permeability material film formed on the IC die to provide concentration of the magnetic field. The Hall sensor system can include at least one permalloy material layer formed on the respective at least one magnetic permeability material film, the at least one magnetic permeability material film and the at least one permalloy material layer combining to provide a magnetic concentrator providing concentration of the magnetic field.

In yet another example, a method for manufacturing a Hall sensor system can include forming a lead frame to conduct a current. The method for manufacturing a Hall sensor system can include fabricating an integrated circuit (IC) die. The method for manufacturing a Hall sensor system can include forming at least one magnetic permeability material film on the IC die. The method for manufacturing a Hall sensor system can include forming at least one magnetic concentrator on the respective at least one magnetic permeability material film, wherein the IC die, the at least one magnetic permeability material film, and the at least one magnetic concentrator combine to form a Hall sensor. The method for manufacturing a Hall sensor system can include providing the Hall sensor on a lead.

### BRIEF DESCRIPTION OF THE DRAWINGS

FIG. 1 illustrates a diagram of an electronic component package for a Hall sensor.

FIG. 2 illustrates a diagram of an electronic component package including a Hall sensor.

FIGS. 3A and 3B illustrates an example of a fabricated Hall sensor.

FIG. 4 illustrates an example diagram of a Hall sensor.

FIG. 5 illustrates a flow diagram for manufacturing an electronic component package.

FIG. 6 illustrates a flow diagram for manufacturing a Hall sensor system.

### DETAILED DESCRIPTION

The present disclosure describes an electronic component package including a Hall sensor and a method of forming a magnetic concentrator. As described herein, by implementing magnetic concentrators of a Hall sensor as a multilayered structure of a thin magnetic permeability film and a permalloy layer, warpage of a wafer on which the circuit die of the Hall sensor is fabricated can be mitigated based on providing the magnetic permeability film as a very thin film, while providing the permalloy layer of the magnetic concentrator ensures sufficient operational capability of the Hall sensor.

As an example, the electronic component package described herein includes a Hall sensor comprising a plurality of Hall sensor elements for sensing magnetic fields in the operating environment. In one example, at least one magnetic concentrator can provide concentration of the magnetic field for sensing by a Hall sensor of the integrated circuit in the electronic component package. As an example, a magnetic permeability material film and a permalloy material layer can be combined via a die attach film to form a magnetic concentrator providing concentration of the magnetic field. The formation of the magnetic concentrator having the combined thin permeability material film and the permalloy material layer mitigates warpage in the wafer on which the integrated circuit is fabricated while maintaining sufficient operating parameters. As described in greater detail herein, by depositing the magnetic permeability material as a very thin film during fabrication of the wafer that includes the circuit die of the Hall sensor, mechanical stress that can cause physical warpage of the wafer (e.g., greater than 400 μm) can be mitigated. The addition of the permalloy material layer on the magnetic concentrator can ensure that the Hall sensor can exhibit sufficient magnetic field concentration despite the small dimensions of the very thin magnetic permeability material film for proper operation of the Hall sensor.

The integrated circuit having the layered magnetic concentrators, as described herein, includes forming the magnetic permeability material film configured in a reduced diameter and a reduced thickness relative to conventional Hall sensors. In an example, the magnetic permeability material film can be a thin plated layer (e.g., nickel-iron). The permalloy material layer can be provided atop the magnetic permeability material film to provide a sufficient magnetic coupling of the magnetic concentrator structure (e.g., greater than approximately 0.41 mT/A). The magnetic concentrator structure comprising the magnetic permeability material film and the permalloy material layer enables the Hall sensor to operate with sufficient magnetic coupling to detect an amplitude of current flow through an associated lead frame.

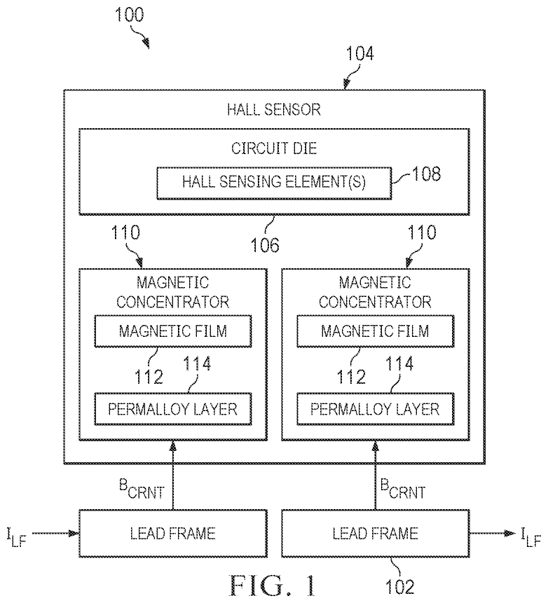

Referring to FIG. 1, a block diagram of an electronic component package 100 in accordance with the disclosure is depicted. The electronic component package 100 includes a lead frame 102 having a Hall sensor 104 electrically coupled to the lead frame 102 for detecting the magnetic field produced by the flow of a current I_{LF} through the lead frame 102. The Hall sensor 104 can include a circuit die 106 comprising one or more Hall sensing elements 108 and one or more magnetic concentrators 110 comprising a magnetic permeability material film 112 and a permalloy material layer 114. For example, the magnetic concentrator 110 can be formed in a layered configuration that includes the permalloy material layer 114 stacked on the magnetic permeability material film 112 on the surface of the lead frame 102 and bonded by a die attach film (not shown).

The circuit die 106 of the Hall sensor 104 can be provided on the surface of the lead frame 102. The Hall sensing elements 108 and the sensor circuitry (not shown) can be configured to be planar with or embedded in the surface of the circuit die 106. In another example, the Hall sensing elements 108 and the sensor circuitry can be provided on the surface of the circuit die 106. The Hall sensing elements 108 can be a device made of a type IV semiconductor material (e.g., Silicon (Si) or Germanium (Ge)) or a type III-V semiconductor material (e.g., Gallium-Arsenide (GaAs) or Indium-Antimonide (InSb)).

In an example, the circuit die 106 in which the Hall sensing elements 108 can be formed can be attached to the lead frame 102 by various techniques, such as with solder bumps or wire bonding. The lead frame 102 can take various forms and the circuit die 106 can be attached to the lead frame 102 in an orientation with the active surface of the circuit die 106 (e.g., the surface in which the Hall sensing elements 108 are formed) being adjacent to the lead frame in a flip-chip arrangement, with the active surface of the circuit die 106 opposite the lead frame surface in a die up arrangement, or with the circuit die 106 positioned below the lead frame 102 in a lead on chip arrangement.

The magnetic concentrators 110 can be configured to include a layer comprised of a magnetic permeability material film 112 (e.g., Nickel-Iron). The magnetic concentrators 110 can be provided on or near the surface of the circuit die arranged such that a magnetic field B_{CRNT} resulting from the current I_{LF} through the lead frame can be concentrated in the magnetic concentrators 110, thereby facilitating detection of the magnetic field B_{CRNT} by the Hall sensing elements 108. FIG. 1 shows the magnetic field B_{CRNT} that can be generated by the flow of a current I_{LF} through the lead frame 102 (e.g., arranged in a 180° bend), such that the Hall sensor 104 can measure an amplitude of the current I_{LF} based on the measured magnitude of the magnetic field B_{CRNT}. A first surface of the magnetic permeability material film 112 can be in contact with the surface of the circuit die 106 and a second surface of the magnetic permeability material film 112, opposite the first surface, can be in contact with and bonded to the permalloy material layer 114.

Some conventional Hall sensors can be fabricated by forming magnetic concentrators solely from a magnetic permeability material film (e.g., NiFe). However, to achieve sufficient magnetic coupling to facilitate proper operation of the Hall sensor, the magnetic permeability material film on the conventional Hall sensor is formed having larger dimensions (e.g., at least 42 μm thick and approximately 1000 μm in diameter). Such large size of the magnetic permeability material film on a conventional Hall sensor can result in unacceptably excessive warpage of the wafer on which the conventional Hall sensor circuits are fabricated. However, as described herein, by forming each of the magnetic concentrators 110 from a combination of the magnetic permeability material film 112 and the permalloy material layer 114, the magnetic concentrators 110 can exhibit sufficient magnetic coupling (e.g., greater than approximately 0.41 mT/A) while also mitigating the warpage of the wafer on which the circuit die 106 is fabricated.

As a first example, the magnetic permeability material film 112 can have a thickness of between approximately 20-25 μm and a diameter of between approximately 900-1000 μm. As a second example, the magnetic permeability material film 112 can have a thickness of between approximately 30-38 μm and a diameter of between approximately 800-900 μm. In either example, the permalloy material layer 114 can have a thickness of between approximately 95-105 μm, and can have a length/width dimension of between approximately 600 and 900 μm. The reduction of the size and thickness of the magnetic permeability material film 112 relative to the magnetic permeability material film of a conventional Hall sensor can aid in the reduction of warpage occurring in the wafer on which the circuit die 106 is fabricated, while the addition of the permalloy material layer 114 can provide for the magnetic coupling to provide for sufficient operation of the Hall sensor 104.

The combination of the magnetic permeability material film 112 and the permalloy material layer 114 are configured to form the structure of the magnetic concentrators 110 to enable concentration of the magnetic field B_{CRNT}, such as in high current operations (e.g., approximately 200 A or greater). Sufficient magnetic coupling (e.g., greater than approximately 0.41 mT/A) can be maintained by the magnetic concentrators 110 based on the fabrication of the magnetic concentrators 110 to include the permalloy material layer 114 without the risk of warpage in the wafer on which the electronic component package 100 is fabricated.

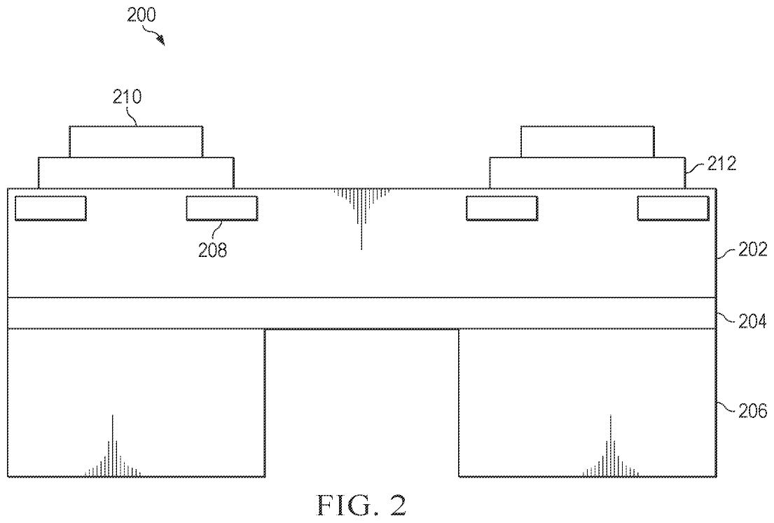

Turning now to FIG. 2, a diagram of an electronic component package 200 including a Hall sensor in accordance with the disclosure is depicted. The electronic component package 200 includes a circuit die 202 having a first active surface in which one or more Hall sensing elements 208 are disposed and a second, opposing surface attached to an isolation layer 204 on a first surface of a lead frame 206.

Conventional techniques for securing the circuit die 202 to the isolation layer 204 include the use of adhesives (e.g., epoxy or an adhesive tape). In an example, the isolation layer 204 can be a contiguous area separating the circuit die 202 from the lead frame 206 to electrically isolate and mechanically protect the circuit die 202 and the enclosed portion of the lead frame 206. Suitable materials for the isolation layer 204 can include thermoset and thermoplastic mold compounds and other commercially available IC mold compounds as long as such material is electrically non-conductive. The isolation layer 204 is applied to the lead frame 206 and circuit die 202 to enclose the circuit die 202 and a portion of the lead frame 206.

A magnetic concentrator can be provided by a first layer 210 of permalloy material formed over a second layer 212 formed of a magnetic permeability material film. Various conventional wafer level packaging techniques may be used to provide the first layer 210 such as pouring, molding, or coating to provide a shielding effect for the second layer 212. The second layer 212 can be provided as a film of a soft ferromagnetic material (e.g., NiFe). In one example, the first layer 210 can have a first surface that opposes a second surface of each respective one of the second layer 212 whereby the first and second surfaces can have a different surface area. The second layer 212 can have a relative smaller thickness (e.g., approximately 20-25 microns) and a relatively larger diameter (e.g., approximately 900-1000 microns) in a first example. Alternatively, the second layer 212 can have a relative larger thickness (e.g., approximately 20-38 microns) and a relatively smaller diameter (e.g., approximately 800-900 microns) in a second example. In either example, the first layer 210 can have a thickness of approximately 95-105 μm and a length/width dimension of approximately 600-900 μm to achieve a sufficient magnetic coupling of greater than approximately 0.41 mT/A to facilitate proper detection of the magnetic field B_{CRNT}.

It will be appreciated by those of ordinary skill in the art that while the active surface of the circuit die 202 is described herein as the surface “in” which the Hall sensing elements 208 are disposed or formed as is the case with certain types of magnetic field elements (e.g., Hall plate), the element can be disposed “over” or “on” the active surface (e.g., magnetoresistance elements). For simplicity of explanation however, while the examples described herein can utilize any suitable type of magnetic field sensing elements, such elements will be described generally herein as being formed or disposed “in” the active surface of the circuit die 202.

In use, the electronic component package 200 described herein can be configured to monitor the magnetic field B_{CRNT} generated by the current ILE provided through the lead frame 206 via the associated Hall sensor (e.g., the Hall sensing elements 208). Therefore, the electronic component package 200 can determine the amplitude of the current I_{LF} through the lead frame 206 based on the magnitude of the magnetic field B_{CRNT}.

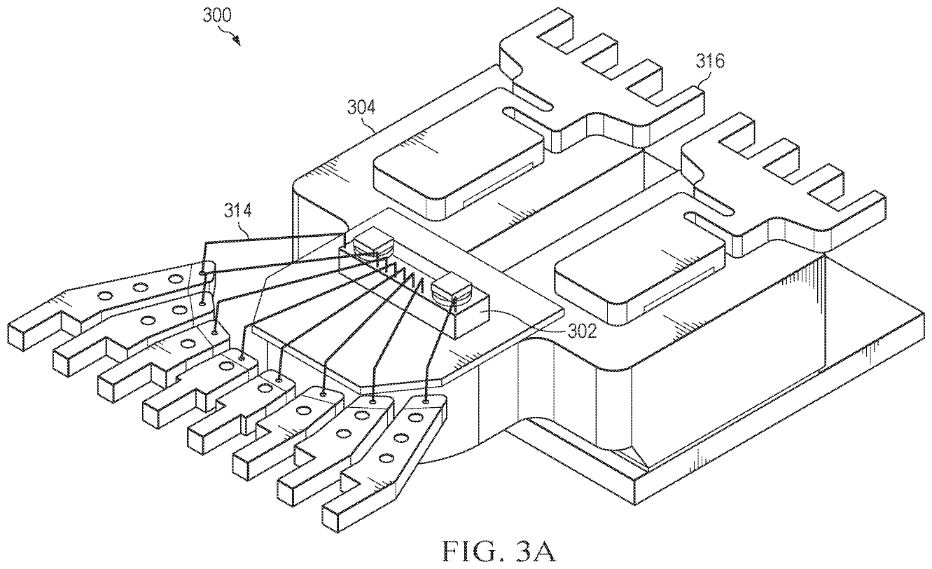

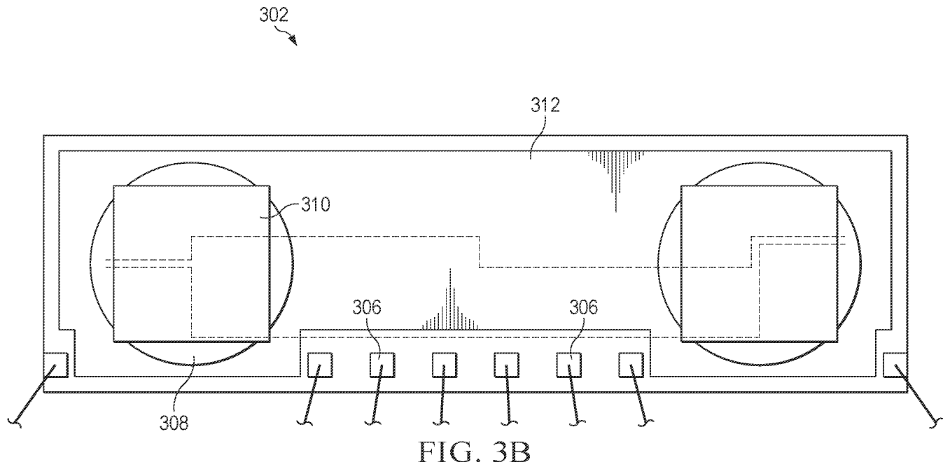

Turning now to FIGS. 3A and 3B, a fabricated Hall sensor system 300 in accordance with the disclosure is depicted. The Hall sensor system 300 includes a Hall sensor 302 bonded to a lead frame 304. The Hall sensor 302 can be provided in applications for determining an amplitude of current through the lead frame 304 based on detecting a magnetic field associated with the current through the lead frame 304. The Hall sensor 302 can provide detection of a magnetic field generated by the current provided through the lead frame (e.g., via Hall sensor elements in the associated circuit die 312), and can provide an output signal (e.g., an output voltage) having a magnitude corresponding to the magnetic field. At least one magnetic permeability material film 308 and at least one permalloy material layer 310 can be provided on the circuit die 312 of the Hall senor 302. The magnetic permeability material film 308 and the permalloy material layer 310 can each be combined to provide a magnetic concentrator providing concentration of the magnetic field generated by the current flowing through the lead frame 304.

The Hall sensor 302 is demonstrated as an eight pin Single In-Line package, but can include any number of pins, as appropriate. The Hall sensor 302 can be separated from the lead frame 304 by an isolation layer to electrically isolate the conductive lead frame 304 and the circuit die 312. The isolation layer can be formed with a non-conductive material having sufficient dielectric constant to insulate the circuit 312 from the high current provided in the lead frame 304. Conventional techniques for securing the circuit die 312 to isolation layer include the use of adhesives, such as epoxy or an adhesive tape.

In one example, a plurality of leads 314 can extend from beyond the circuit die 312 to pins of an associated package that are in electrical communication with the circuit die 312. A plurality of lead terminals 306 can be provided on the circuit die 312 to provide electrical contact with the leads 314. The plurality of leads 314 can be provided for input and output signals associated with the active circuitry of the Hall sensor 302. FIG. 3A shows a top view of the Hall sensor 302 whereby one or more connection terminals 316 can be provided in electrical communication with the lead frame 304 to provide the current connection to the lead frame of the magnetic field sensor 300.

During the fabrication of the circuit die 312, the Hall sensor elements are formed within the circuit die 312. The magnetic concentrator including the magnetic permeability material film 308 and the permalloy material layer 310 is formed above the Hall sensor elements on the circuit die 312. The magnetic permeability material film 308 of the magnetic concentrator is formed on the upper surface of the circuit die 312. The permalloy material layer is formed on the magnetic permeability material film 308 by any suitable deposition process. In an example, the magnetic permeability material film 308 can be formed having predefined dimensions (e.g., approximately 20-25 μm thick and approximately 900-1000 μm diameter or approximately 30-38 μm thick and approximately 800-900 μm diameter) to mitigate warpage of the wafer on which the circuit die 312 is fabricated during deposition of the magnetic permeability material film 308. By including a layer of permalloy material 310 on the magnetic permeability material film 308 to form the magnetic concentrator, the magnetic concentrator as described herein can operate to provide a magnetic coupling (e.g., greater than approximately 0.41 mT/A) that is operationally sufficient to accurately determine the amplitude of the current through lead frame 304.

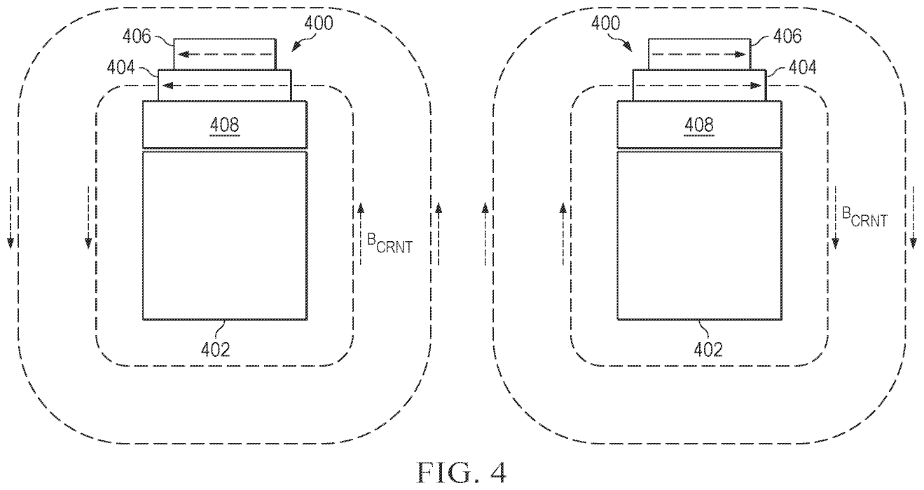

Turning now to FIG. 4, an example of a Hall sensor 400 demonstrated in a cross-sectional view in accordance with the disclosure is depicted. The Hall sensor 400 can be configured to detect the magnetic field B_{CRNT} generated by the current I_{LF} flowing through a lead frame 402. In the example of FIG. 4, similar to as demonstrated in the examples of FIGS. 3A and 3B, the shape of the lead frame 402 as having a 180° bend demonstrates the magnetic field BURNT counter-rotating about the two portions of the lead frame 402. The circuit die 408 is demonstrated as cut-away in the middle (between the two portions of the lead frame 402) for ease in illustrating the magnetic field B_{CRNT}.

The magnetic field sensor 400 can measure the magnetic field B_{CRNT}, and thus the current I_{LF}. In the example of FIG. 4, the magnetic field B_{CRNT} is concentrated in the magnetic concentrator formed by the magnetic permeability material film 404 and the permalloy material layer 406 on the circuit die 408. The combination of the magnetic permeability material film 404 and the permalloy material layer 406 can provided for sufficient magnetic coupling (e.g., greater than approximately 0.41 mT/A) to accurately detect the magnetic field B_{CRNT}, such as to determine a precise measurement of the current I_{LF} through the lead frame 402. However, by providing the magnetic permeability material film 404 as a thin film during fabrication of the Hall sensor 400, warpage in the associated wafer on which the circuit die 408 is fabricated can be sufficiently mitigated (e.g., less than approximately 400 μm).

The foregoing outlines features of several examples so that that those skilled in the art may better understand the aspects of the present disclosure. Those skilled in the art should appreciate that they may readily use the present disclosure as a basis for designing or modifying other processes and structures for carrying out the same purposes and/or achieving the same advantages of the examples introduced herein. Those skilled in the art should also realize that such equivalent constructions do not depart from the spirit and scope of the present disclosure, and that they may make various changes, substitutions, alterations herein without departing from the spirit and scope of the present disclosure.

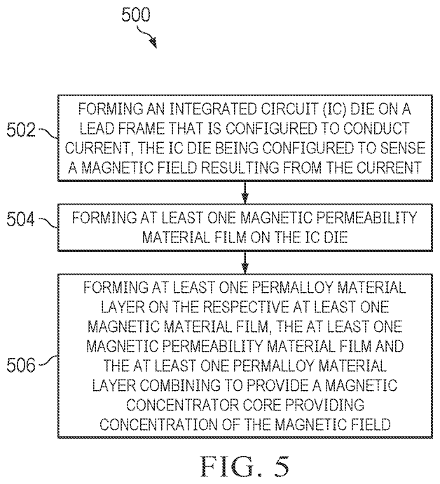

Referring now to the example of FIG. 5, illustrated is a flow diagram 500 for forming an electronic component package in accordance with one or more examples described herein.

At 502, the flow diagram comprises forming an integrated circuit (IC) die on a lead frame that is configured to conduct current, the IC die being configured to sense a magnetic field resulting from the current.

At 504, the flow diagram comprises forming at least one magnetic permeability material film on the IC die.

At 506, the flow diagram comprises forming at least one permalloy material layer on the respective at least one magnetic material film, the at least one magnetic permeability material film and the at least one permalloy material layer combining to provide a magnetic concentrator providing concentration of the magnetic field.

The method of manufacturing the electronic component package further includes each of the at least one permalloy layer having a first surface that opposes a second surface of each respective one of the at least one magnetic permeability material film, wherein the first and second surfaces have different surface areas.

The method of manufacturing the electronic component package further includes the at least one magnetic permeability material film having a thickness of between approximately 20-25 μm and a diameter of between approximately 900-1000 μm, wherein the at least one permalloy material layer having a thickness of between approximately 95-105 μm and a diameter of between approximately 600-900 μm.

The method of forming the magnetic permeability material film further includes the at least one magnetic permeability material film having a thickness of between approximately 30-38 μm and a diameter of between approximately 800-900 μm.

The method of manufacturing the electronic component package further includes the magnetic concentrator providing a magnetic coupling of greater than 0.41 mT/A in current operation greater than 200 A.

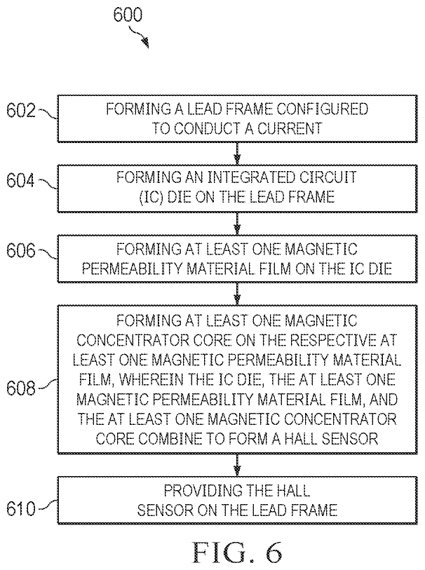

Referring now to the example of FIG. 6, illustrated is a flow diagram 500 for forming a Hall sensor system in accordance with one or more examples described herein.

At 602, the flow diagram comprises forming a lead frame configured to conduct a current.

At 604, the flow diagram comprises forming an integrated circuit (IC) die on the lead frame.

At 606, the flow diagram comprises forming at least one magnetic permeability material film on the IC die.

At 608, the flow diagram comprises forming at least one magnetic concentrator on the respective at least one magnetic permeability material film, wherein the IC die, the at least one magnetic permeability material film, and the at least one magnetic concentrator combine to form a Hall sensor.

At 610, the flow diagram comprises providing the Hall sensor on the lead frame.

The method of manufacturing the Hall sensor system further includes each of the at least one permalloy layer having a first surface that opposes a second surface of each respective one of the at least one magnetic permeability material film, wherein the first and second surfaces have different surface areas.

The method of manufacturing the Hall sensor system further includes the at least one magnetic permeability material film having a thickness of between approximately 20-25 μm and a diameter of between approximately 900-1000 μm, wherein the at least one permalloy material layer having a thickness of between approximately 95-105 μm and a diameter of between approximately 600-900 μm.

The method of forming the magnetic permeability material film further includes the at least one magnetic permeability material film having a thickness of between approximately 30-38 μm and a diameter of between approximately 800-900 μm.

The method of manufacturing the Hall sensor system further includes the magnetic concentrator providing a magnetic coupling of greater than 0.41 mT/A in current operation greater than 200 A.

The foregoing detailed description is merely illustrative and is not intended to limit examples and/or application or uses of examples. Furthermore, there is no intention to be bound by any expressed or implied information presented in the preceding Background or Summary sections, or in the Detailed Description section.

As used in the specification and the appended claims, the singular forms “a,” “an,” and “the” are intended to include the plural forms as well, unless the context clearly indicates otherwise.

Unless otherwise indicated, any element, property, feature, or combination of elements, properties, and features, may be used in any example disclosed herein, regardless of whether the element, property, feature, or combination was explicitly disclosed in the example. It will be readily understood that features described in relation to any particular aspect described herein may be applicable to other aspects described herein provided the features are compatible with that aspect. In particular, features described herein in relation to the method may be applicable to the magnetic field sensing product and vice versa.

Reference throughout this specification to “one example,” or “an example,” means that a particular feature, structure, or characteristic described in connection with the example is included in at least one example. Thus, the appearances of the phrase “in one example,” “in one aspect,” or “in an example,” in various places throughout this specification are not necessarily all referring to the same example. Furthermore, the particular features, structures, or characteristics may be combined in any suitable manner in one or more examples.

The words “exemplary” and/or “demonstrative” are used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive—in a manner similar to the term “comprising” as an open transition word-without precluding any additional or other elements.

The above description includes non-limiting aspects of the various examples. It is, of course, not possible to describe every conceivable combination of components or methods for purposes of describing the disclosed subject matter, and one skilled in the art may recognize that further combinations and permutations of various examples are possible. The disclosed subject matter is intended to embrace all such alterations, modifications, and variations that fall within the spirit of the appended claims.

With regard to the various functions performed by the above described components, the terms (including a reference to a “means”) used to describe such components are intended to also include, unless otherwise indicated, any structure(s) which performs the specified function of the described component (e.g., functional equivalent), even if not structurally equivalent to the disclosed structure. In addition, while a particular feature of the disclosed subject matter may have been disclosed with respect to only one of several implementations, such feature may be combined with one or more features of the other implementations as may be desired and advantageous for any given or particular applications.

The terms “exemplary” and/or “demonstrative” as used herein are intended to mean serving as an example, instance, or illustrative. For the avoidance of doubt, the subject matter disclosed herein is not limited to such examples. In addition, any aspect or design described herein as “exemplary” and/or “demonstrative” is not necessarily to be construed as preferred or advantageous over the other aspects or designs, nor is it meant to preclude equivalent structures and techniques known to one skilled in the art. Furthermore, to the extent that the terms “includes,” “has,” “contains,” and other similar words are used in either the detailed description or the claims, such terms are intended to be inclusive—in a manner similar to the term “comprising” as an open transition word-without precluding any additional or other elements.

What is claimed is:

1. An electronic component package, comprising:
an IC die formed on a lead frame that is configured to conduct a current, the IC die being configured to sense a magnetic field resulting from the current;
at least one magnetic permeability material film formed on the IC die; and
at least one permalloy material layer formed on the respective at least one magnetic permeability material film, the at least one magnetic permeability material film and the at least one permalloy material layer combining to provide a magnetic concentrator providing concentration of the magnetic field.

2. The electronic component package of claim 1, wherein each of the at least one permalloy layer has a first surface that opposes a second surface of each respective one of the at least one magnetic permeability material film, wherein the first and second surfaces have different surface areas.

3. The electronic component package of claim 1, wherein the at least one magnetic permeability material film has a thickness of between approximately 20-25 μm and a diameter of between approximately 900-1000 μm, wherein the at least one permalloy material layer has a thickness of between approximately 95-105 μm and a diameter of between approximately 600-900 μm.

4. The electronic component package of claim 1, wherein the at least one magnetic permeability material film has a thickness of between approximately 30-38 μm and a diameter of between approximately 800-900 μm.

5. The electronic component package of claim 1, wherein the magnetic concentrator provides a magnetic coupling of greater than 0.41 mT/A in current operation greater than 200 A.

6. A method of manufacturing an electronic component package;
forming an integrated circuit (IC) die on a lead frame that is configured to conduct current, the IC die being configured to sense a magnetic field resulting from the current;
forming at least one magnetic permeability material film formed on the IC die; and
forming at least one permalloy material layer formed on the respective at least one magnetic material film, the at least one magnetic permeability material film and the at least one permalloy material layer combining to provide a magnetic concentrator providing concentration of the magnetic field.

7. The method of claim 6, wherein each of the at least one permalloy layer has a first surface that opposes a second surface of each respective one of the at least one magnetic permeability material film, wherein the first and second surfaces have different surface areas.

8. The method of claim 6, wherein the at least one magnetic permeability material film has a thickness of between approximately 20-25 μm and a diameter of between approximately 900-1000 μm, wherein the at least one permalloy material layer has a thickness of between approximately 95-105 μm and a diameter of between approximately 600-900 μm.

9. The method of claim 6, wherein the at least one magnetic permeability material film has a thickness of between approximately 30-38 μm and a diameter of between approximately 800-900 μm.

10. The method of claim 6, wherein the magnetic concentrator provides a magnetic coupling of greater than 0.41 mT/A in current operation greater than 200 A.

11. A Hall sensor system comprising:
a lead frame configured to conduct a current;
an integrated circuit (IC) die formed on the lead frame, the IC die being configured to sense a magnetic field resulting from the current;
at least one magnetic permeability material film formed on the IC die to provide concentration of the magnetic field; and
at least one permalloy material layer formed on the respective at least one magnetic permeability material film, the at least one magnetic permeability material film and the at least one permalloy material layer combining to provide a magnetic concentrator providing concentration of the magnetic field.

12. The Hall sensor system of claim 11, wherein each of the at least one permalloy layer has a first surface that opposes a second surface of each respective one of the at least one magnetic permeability material film, wherein the first and second surfaces have different surface areas.

13. The Hall sensor system of claim 11, wherein the at least one magnetic permeability material film has a thickness of between approximately 20-25 μm and a diameter of between approximately 900-1000 μm, wherein the at least one permalloy material layer has a thickness of between approximately 95-105 μm and a diameter of between approximately 600-900 μm.

14. The Hall sensor system of claim 11, wherein the at least one magnetic permeability material film has a thickness of between approximately 30-38 μm and a diameter of between approximately 800-900 μm.

15. The Hall sensor system of claim 11, wherein the magnetic concentrator provides a magnetic coupling of greater than 0.41 mT/A in current operation greater than 200 A.

16. A method for manufacturing a Hall sensor system, the method comprising:
forming a lead frame configured to conduct a current;
fabricating an integrated circuit (IC) die on the lead frame;
forming at least one magnetic permeability material film on the IC die;
forming at least one magnetic concentrator on the respective at least one magnetic permeability material film, wherein the IC die, the at least one magnetic permeability material film, and the at least one magnetic concentrator combine to form a Hall sensor; and
providing the Hall sensor on the lead frame.

17. The method of claim 16, wherein each of the at least one permalloy layer has a first surface that opposes a second surface of each respective one of the at least one magnetic permeability material film, wherein the first and second surfaces have different surface areas.

18. The method of claim 16, wherein the at least one magnetic permeability material film has a thickness of between approximately 20-25 μm and a diameter of between approximately 900-1000 μm, wherein the at least one permalloy material layer has a thickness of between approximately 95-105 μm and a diameter of between approximately 600-900 μm.

19. The method of claim 18, wherein the at least one magnetic permeability material film has a thickness of between approximately 30-38 μm and a diameter of between approximately 800-900 μm.

20. The method of claim 16, wherein the magnetic concentrator provides a magnetic coupling of greater than 0.41 mT/A in current operation greater than 200 A.
